(19) United States
(12) Patent Application Publication
(10) Pub. No.: US 2004/0166600 A1
(43) Pub. Date: Aug. 26, 2004

(54) Display

(75) Inventors: Masakazu Sagawa, Inagi (JP); Makoto Okai, Tokorozawa (JP); Fumikazu Mizutani, Inashiki-gun (JP); Hiroshi Takaha, Inashiki-gun (JP); Makoto Ue, Inashiki-gun (JP)

Correspondence Address: REED SMITH LLP, Suite 1400, 3110 Fairview Park Drive, Falls Church, VA, 22042, US

(73) Assignees: Hitachi, Ltd.; Mitsubishi Chemical Corporation

(21) Appl. No.: 10/754,556

(22) Filed: Jan. 12, 2004

Related U.S. Application Data
(62) Division of application No. 09/959,953, filed on Dec. 31, 2001.
Application No. 09/959,953 is a 371 of international application No. PCT/JP00/02979, filed on May 10, 2000.

(30) Foreign Application Priority Data
May 17, 1999 (JP) 11-135316

(51) Int. Cl. H01L 21/00

(52) U.S. Cl. 438/29

(57) ABSTRACT

A display having a second substrate with a phosphor layer formed on the surface and a first substrate disposed opposing to the first substrate and having electron guns formed thereon, said electron guns having a structure of: first conductive film laminated on the first substrate—insulating film—second conductive film, and said insulating film being one formed by anodizing the first conductive film by using a non-aqueous electrolyte containing an organic solvent such as a compound having an alcoholic hydroxyl group and at least one solute selected from salts of inorganic oxo acids and salts of organic carboxylic acids. According to this device, the quality of the insulating film forming the tunneling insulator of electron guns of the MIM diode structure is improved to prolong the service life of the device.

### TECHNICAL FIELD

The present invention relates to a display, more particularly to a display using electron guns of a metal-insulator-metal (MIM) tunnel diode structure.

### BACKGROUND ART

A display using electron guns of an MIM tunnel diode structure is disclosed in the following literature (i):

(i) M. Suzuki and T. Kusunoki: Emission and Beam-Divergence Properties of an MIM-Cathode Array for Display Applications, SID 97 DIGEST (1997)

The electron guns of the MIM diode structure disclosed in the above literature (i), which feature high efficiency and high directionality, are notable for their micro-structure in which the thickness of the tunneling insulator is only 5.5 nm while the top electrodes serving as electron emitters are designed to have a thickness of as small as 6 nm to avoid diffusion of hot electrons.

In the electron guns of the MIM diode structure such as described in the above literature (i), necessarily for their structure, a high electric field of approximately 10 MV/cm is applied to the tunneling insulator and a current of about 0.4 mA/cm² flows therein during operation.

Under such harsh conditions, degradation with time of the insulating film forming the tunneling insulator is unavoidable.

Observing the change with time of the tunnel diode performance, it is noted that the diode current falls off with time, ending up with breakdown.

This phenomenon may be accounted for by the fact that in the insulating film forming the tunneling insulator, part of the injected hot electrons are captured by the electron traps in the insulating film to become the fixed minus charge, which weakens the electric field on the cathode side to restrain electron injection.

The fact that the degradation is not saturated with time indicates the successive formation of new electron traps by hot electrons in the high electric field.

This phenomenon has been a major restrictive factor of operating life of the electron guns of the MIM diode structure.

The insulating film forming the tunneling insulator has been formed by anodic oxidation using as the electrolyte a 1-3 wt % tartaric acid solution neutralized with ammonic aqueous solution and diluted with ethylene glycol, with the formation current density being defined to 100 μA/cm² or below.

This method was capable of providing good initial characteristics but had difficulties in maintaining such characteristics for a long time.

### DISCLOSURE OF THE INVENTION

The present invention has been made for solving the said prior art problems, and the object thereof is to provide a display by making use of the novel techniques that enable improvement of quality of the insulating film forming the tunneling insulator of the electron guns of the MIM diode structure and prolongation of operating life of the electron guns.

The present invention provides a display having a second substrate with a phosphor layer formed on the surface and a first substrate disposed opposing to said second substrate and having electron guns formed thereon, said electron guns having a structure of: first conductive film (bottom electrodes) laminated on the first substrate—insulating film—second conductive film (top electrodes), said insulating film having been formed by anodizing said first conductive film by using at least one of the following non-aqueous electrolytes (a)-(c):

(a) a non-aqueous electrolyte containing an organic solvent having an alcoholic hydroxyl group and at least one solute selected from salts of inorganic oxoacids and salts of organic carboxylic acids (limited to salts of aromatic carboxylic acids or salts of aliphatic polycarboxylic acids containing not more than 2 alcoholic hydroxyl groups);

(b) a non-aqueous electrolyte containing an aprotic organic solvent and at least one solute selected from salts of inorganic oxo acids and salts of organic carboxylic acids; and

(c) a non-aqueous electrolyte containing a mixed solvent comprising an organic solvent having an alcoholic hydroxyl group and an aprotic organic solvent, and at least one solute selected from salts of inorganic oxo acids and salts of organic carboxylic acids.

### BRIEF DESCRIPTION OF DRAWINGS

FIG. 1 is an exploded perspective view showing epitomic structure of a display embodying the present invention.

FIG. 2 is a schematic structural illustration of an example of lower substrate (first substrate) shown in FIG. 1.

FIG. 3 is a schematic structural illustration of an example of upper substrate (second substrate) shown in FIG. 1.

FIG. 4 is a schematic illustration of an array of electron guns of the MIM diode structure shown in FIG. 2.

### BEST MODE FOR CARRYING OUT THE INVENTION

Epitomes of typical embodiments of the invention disclosed in the present application are briefly described below.

The present invention relates to a display having a second substrate (upper substrate) with a phosphor layer formed on the surface and a first substrate (lower substrate) disposed opposing to said second substrate and having electron guns formed thereon, said electron guns having a structure of: first conductive film laminated on the first substrate—insulating film—second conductive film, said insulating film being formed by anodizing said first conductive film by using a non-aqueous electrolyte containing an organic solvent having an alcoholic hydroxyl group and at least one solute selected from salts of inorganic oxo acids and salts of organic carboxylic acids (limited to salts of aromatic carboxylic acids or salts of aliphatic polycarboxylic acids containing not more than 2 alcoholic hydroxyl groups).

The present invention also relates to a display having a second substrate (upper substrate) with a phosphor layer formed on the surface and a first substrate (lower substrate) disposed opposing to said second substrate and having electron guns formed thereon, said electron guns having a structure of: first conductive film laminated on the first substrate—insulating film—second conductive film, said insulating film being formed by anodizing said first conductive film by using a non-aqueous electrolyte containing an aprotic organic solvent and at least one solute selected from salts of inorganic oxo acids and salts of organic carboxylic acids.

The present invention further relates to a display having a second substrate (upper substrate) with a phosphor layer formed on the surface and a first substrate (lower substrate) disposed opposing to said second substrate and having electron guns formed thereon, said electron guns having a structure of: first conductive film laminated on the first substrate—insulating film—second conductive film, said insulating film being formed by anodizing said first conductive film by using a non-aqueous electrolyte containing a mixed solvent comprising an organic solvent having an alcoholic hydroxyl group and an aprotic organic solvent and at least one solute selected from salts of inorganic oxo acids and salts of organic carboxylic acids.

Embodiments of the present invention are described in detail below with reference to the accompanying drawings.

In the drawings attached herewith for illustrating the embodiments of the invention, the same reference numerals are used to designate parts having the same functions throughout, and repetition of explanation for the parts is saved to avoid redundancy of the description.

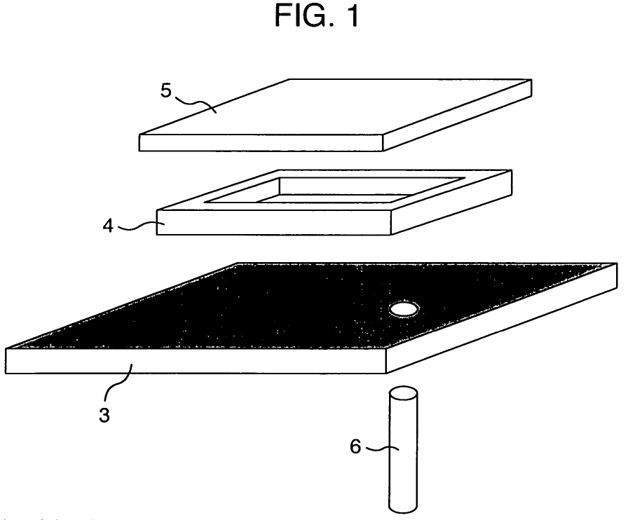

FIG. 1 is a schematic exploded perspective view showing the skeletal structure of the display in an embodiment of the present invention. The device comprises a lower substrate (first substrate) 3 with an array of metal-insulator-metal (MIM) micro-electron guns formed on the surface and an upper substrate (second substrate) 5 having a striped phosphor layer formed thereon, said substrates being set opposing to each other by a glass frame 4. In FIG. 1, numeral 6 designates an exhaust pipe.

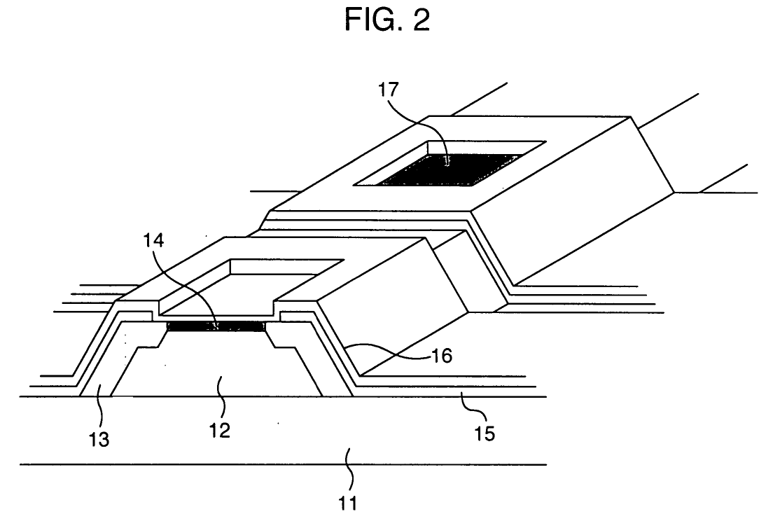

FIG. 2 is a schematic illustration of the structure of an example of lower substrate 3 shown in FIG. 1.

The lower substrate 3 comprises stripes of bottom electrodes 12 formed on a glass (such as soda lime glass) substrate 11 and extending in the x-direction, electric field diffusers (or interlayer insulators) 13 and tunneling insulators 14 formed on said bottom electrodes 12, stripes of bus electrodes formed on said tunneling insulators 14 and extending in the y-direction, and top electrodes 6 formed on said bus electrodes 15.

Said bottom electrodes 12 and bus electrodes 15 are arranged at substantially right angles to each other, and an electron emission region 17 is formed at a part of the area where said both electrodes 12 and 15 overlap each other.

In this electron emission region 17, bus electrodes 15 are cleared away, and top electrodes 16 are positioned opposing to bottom electrodes 12 with tunneling insulator 14 interposed between them.

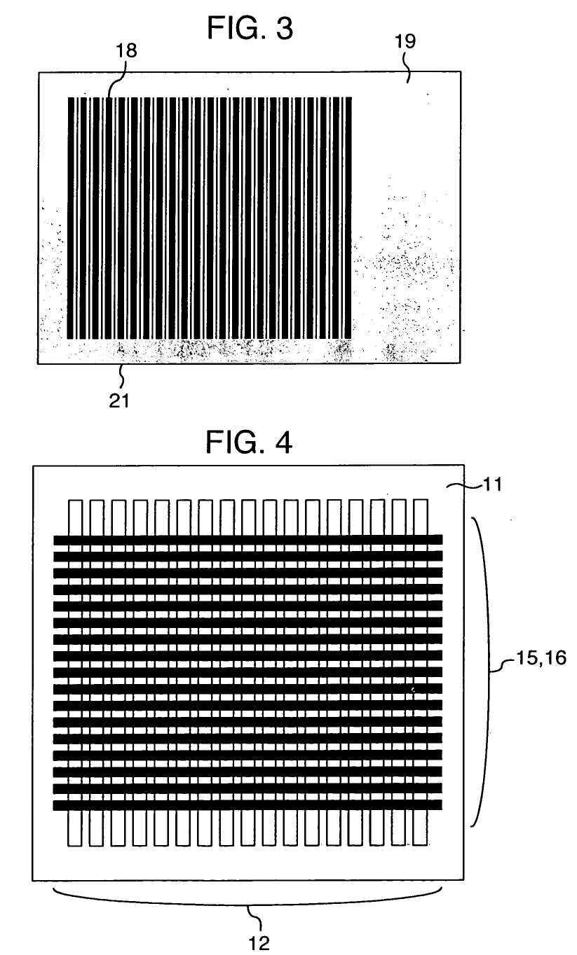

FIG. 3 is a schematic illustration of the structure of an example of upper substrate 5 shown in FIG. 1.

Upper substrate 5 shown in FIG. 3 comprises a glass (such as soda lime glass) base 21, phosphor stripes 18 formed thereon and containing stripes of red, green and blue phosphor layers extending in the y-direction, and a metal-back film (Al film) 19 formed on said phosphor stripes 18.

The display according to the present invention is characterized in that tunneling insulator 14 shown in FIG. 2 is composed of an insulating film formed by anodizing bottom electrodes 12 by using a non-aqueous electrolyte (a) containing an organic solvent having an alcoholic hydroxyl group and at least one solute selected from salts of inorganic oxo acids and salts of organic carboxylic acids (limited to salts of aromatic carboxylic acids or salts of aliphatic polycarboxylic acids containing not more than 2 alcoholic hydroxyl groups).

In the display of the present invention, tunneling insulator 14 shown in FIG. 2 may be composed of an insulating film formed by anodizing bottom electrodes 12 by using a non-aqueous electrolyte (b) containing an aprotic organic solvent and at least one solute selected from salts of inorganic oxo acids and salts of organic carboxylic acids.

Also, in the display according to the present invention, tunneling insulator 14 shown in FIG. 2 may comprise an insulating film formed by anodizing bottom electrodes 12 by using a non-aqueous electrolyte (c) containing a mixed solvent comprising an organic solvent having an alcoholic hydroxyl group and an aprotic organic solvent and at least one solute selected from salts of inorganic oxo acids and salts of organic carboxylic acids.

As the salt of an inorganic acid used as the solute of the forming electrolyte in the present invention, it is preferred to use a salt of an inorganic oxo acid. The inorganic oxo acid is an inorganic acid having a hydrogen atom which is bound to the oxygen atom, and can be dissociated as a proton, and its central atom may be either nonmetallic or metallic element.

Specifically, as such inorganic oxo acid, it is preferred to use one or more compounds selected from boric acid, phosphoric acid, sulfuric acid, tungstic acid, molybdic acid, chromic acid, vanadic acid and perrhenic acid.

The salt of organic carboxylic acid used as the solute of the forming electrolyte in the present invention can be selected from various salts of organic compounds having a carboxyl group. The number and the bonding position of the carboxyl group are not particularly limited. Preferred are salts of aromatic carboxylic acids and aliphatic polycarboxylic acids.

As the aromatic carboxylic acids, those compounds having a benzene ring, condensed benzene ring, non-benzene aromatic ring, heteroaromatic ring or the like, and a carboxyl group can be used.

As the aromatic carboxylic acid which does not contain a hetero atom, there can be exemplified salicylic acid, phthalic acid, benzoic acid, γ-resorcylic acid, toluic acid, cumilic acid, t-butylbenzoic acid, anisinic acid, 2,4-cresotinic acid, cinnamic acid, N-methylanthranilic acid, gentisic acid, gallic acid, and p-hydroxybenzoic acid. As the hetero aromatic carboxylic acid, nicotinic acid, 2-froinic acid, 2-tenoinic acid and hydrazylbenzoic acid can be exemplified.

Furthermore, so long as the desired advantages of the present invention are not degraded, aromatic carboxylic acids which have functional groups other than carboxyl group can also be used. For example, aromatic carboxylic acids that have a nitro group or an amino group such as nitrobenzoic acid, anthranilic acid, monomethylaminobenzoic acid, and dimethylaminobenzoic acid can also be used.

As the aliphatic polycarboxylic acid, there can be exemplified tartaric acid, citric acid, tartronic acid, malic acid, oxalic acid, malonic acid, succinic acid, glutaric acid, adipic acid, pimelic acid, suberic acid, azelaic acid, sebacic acid, dimethylmalonic acid, diethylmalonic acid, dipropylmalonic acid, 2-methylglutaric acid, 3,3-dimethylglutaric acid, 3-methyladipic acid, maleic acid, fumaric acid, itaconic acid, citraconic acid, 2-methyleneglutaric acid, 2-methyl-2-pentadicarboxylic acid and the like.

In case where a solvent having an alcoholic hydroxyl group is used as electrolyte, the salt of organic carboxylic acid used as solute is preferably selected from the group consisting of salts of aromatic carboxylic acids and salts of aliphatic polycarboxylic acids containing not more than 2 alcoholic hydroxyl groups. As the salts of aromatic carboxylic acids, the compounds exemplified above can be cited here, too.

The salts of aliphatic polycarboxylic acids are not particularly restricted in their structure as far as they are the aliphatic compounds containing not more than 2 alcoholic hydroxyl groups and having two carboxyl groups. In case of using an aliphatic polycarboxylic acid, it is preferably one with a carbon number of 3 to 9. This acid, therefore, may or may not have an unsaturated bond in the molecule.

It is also possible to use aliphatic polycarboxylic acids having functional groups other than carboxyl group as far as the intended effect of the present invention won't be impaired.

Examples of the aliphatic polycarboxylic acids usable in the present invention include citric acid, tartronic acid, malic acid, oxalic acid, malonic acid, succinic acid, glutaric acid, adipic acid, pimelic acid, suberic acid, azelaic acid, sebacic acid, dimethylmalonic acid, diethylmalonic acid, dipropylmalonic acid, 2-methylglutaric acid, 3,3-dimethylglutaric acid, 3-methyladipic acid, maleic acid, fumaric acid, citraconic acid, 2-methyleneglutaric acid, 2-methyl-2-pentadicarboxylic acid and the like.

Among the above-mentioned inorganic oxo acids, boric acid, phosphoric acid, sulfuric acid, tungstic acid, molybdic acid, chromic acid and vanadic acid are preferred, tungstic acid being especially preferred.

In the above-mentioned organic carboxylic acids, salicylic acid, adipic acid, azelaic acid, phthalic acid, benzoic acid, γ-resorcylic acid, maleic acid, fumaric acid, itaconic acid, malonic acid, succinic acid, glutaric acid, dimethylmalonic acid and citraconic acid are preferred, among which salicylic acid, adipic acid, maleic acid, azelaic acid and phthalic acid are especially preferred.

Cations for forming salts of these inorganic acids or organic carboxylic acids are not particularly limited. For example, ammonium ions, alkali metal ions, primary, secondary, tertiary or quaternary alkylammonium ions, phosphonium ions, sulfonium ions and the like can be used. Among these, it is particularly preferred to use ammonium ions, primary, secondary, tertiary or quaternary alkylammonium ions. In the case of using an alkylammonium ion, the size of the alkyl group can be selected considering the solubility in the solvent. Usually, an alkyl group of a carbon number of 1-4 is selected.

These solutes can be used independently or in any combination of two or more of them. It is also possible to use the solutes other than salts of inorganic acids or organic carboxylic acids as a suitable combination.

The solute concentration in the electrolyte used in the present invention is normally set within the range of 0.01 to 30% by weight, preferably 0.1 to 15% by weight.

As the solvent of the forming electrolyte of the present invention, a solvent having an alcoholic hydroxyl group or an aprotic organic solvent is used.

The nature of the compound having an alcoholic hydroxyl group used as the solvent is not particularly limited. Preferred examples are fatty alcohols having an alcoholic hydroxyl group. For example, monohydric alcohols such as methanol, ethanol, propanol, and isopropanol; dihydric alcohols such as ethylene glycol and propylene glycol; and polyhydric alcohols, i.e., trihydric or alcohols having a greater number of hydroxyl groups can be used. Further, so long as the desired advantages of the present invention are not degraded, solvents having a functional group other than alcoholic hydroxyl group in their molecule can also be used. For example, solvents having an alkoxy group in addition to the alcoholic hydroxyl group, for example, methyl Cellosolve or Cellosolve can also be used.

These solvents may be used independently or in any combination of two or more of them. For the forming electrolyte of the present invention, it is preferred to use a solvent having a carbon number of 1-8 as the solvent having an alcoholic hydroxyl group. The particularly preferred solvent is ethylene glycol or propylene glycol, or a mixture thereof.

The aprotic organic solvent used for the forming electrolyte of the present invention as the solvent may be either a polar solvent or nonpolar solvent. Examples of the polar solvent include, for example, lactone solvents such as γ-butyrolactone, γ-valerolactone and δ-valerolactone; carbonate solvents such as ethylene carbonate, propylene carbonate and butylene carbonate; amide solvents such as N-methylformamide, N-ethylformamide, N,N-dimethylformamide, N,N-diethylformamide, N-methylacetamide, N,N-dimethylacetamide and N-methylpyrrolidinone; nitrile solvents such as 3-methoxypropionitrile and glutaronitrile; and phosphate solvents such as trimethyl phosphate and triethyl phosphate.

These solvents may be used independently or in any combination of two or more of them. The particularly preferred solvent for use in the present invention is propylene carbonate or γ-butyrolactone, or a mixture thereof.

In the electrolyte used in the present invention, water is preferably contained in an amount of 0.1 to 50% by weight. The water content is preferably 0.1 to 30% by weight, more preferably 0.1 to 20% by weight, even more preferably 1 to 15% by weight, most preferably 3 to 15% by weight.

In the preparation of the electrolyte used in the present invention, the way of addition of water is not particularly limited. For example, the electrolyte may be prepared by dissolving a solute (or a mixture of solutes) such as mentioned above in a solvent (or a mixture of solvents) such as mentioned above which contains water, or by dissolving a solute (or a mixture of solutes) in a solvent (or a mixture of solvents), such as mentioned above, and then adding water. It is also possible to prepare the electrolyte by making use of water which is formed as a by-product when producing a solute by reacting an acid and a base. These methods may be used in combination.

The conditions under which the insulating film (tunneling insulator) is formed by anodizing the first conductive film (bottom electrodes) by using the forming electrolyte of the present invention are not particularly limited. The anodization temperature is defined within the range in which the electrolyte can stay stable as a liquid, such a temperature range being normally from −20° C. to 150° C., preferably from 10° C. to 100° C.

The method of controlling current and voltage in anodization is also not particularly limited; the conditions used for forming an oxide layer on the metal surface may be applied in a suitable combination. Usually, formation is carried out at a constant current until a predetermined formation voltage (Vf) is reached, and after this formation voltage has been reached, anodization is carried out at a constant voltage for a given period of time. In this operation, current density is set within the range of 1μ to 100 mA/cm², preferably 1μ to 1 mA/cm². Vf is usually set within the range of 0.1 to 50 V, preferably 0.1 to 20 V.

As the metal used for the first conductive film (bottom electrodes), so-called “valve metals”, which are capable of forming a barrier layer by anodization, are used. Aluminum (Al) or an aluminum alloy is preferably used as such metal. Since pure aluminum tends to form hillocks on heat treatment, an alloy containing a trace amount of an element other than aluminum is more preferably used as wiring material.

As the element to be added, rare earth elements such as scandium (Sc), yttrium (Y), lanthanum (La), praseodymium (Pr), neodymium (Nd), gadolinium (Gd), holmium (Ho) and erbium (Er), and “valve metal” elements such as titanium (Ti), tantalum (Ta), zirconium (Zr), hafnium (Hf), niobium (Nb), tungsten (W) and molybdenum (Mo) can be exemplified. Silicon (Si) and copper (Cu) are also usable. Aluminum alloys containing neodymium (Nd) are particularly preferred for the first conductive film in the present invention.

As the second conductive film (top electrodes), a film of Ir, Pt, Au or the like formed by shadow mask evaporation can be used.

The display of the present invention is further explained with reference to its examples.

### EXAMPLES 1-8 AND COMPARATIVE EXAMPLE 1

In these examples, first of all, electron guns were formed by the following process.

(1) An Al—Nd (2 atom %) alloy was sputter-deposited to a thickness of 300 nm on a glass substrate 11 to form bottom electrodes (first conductive film) by photolithography.

(2) Then, the portion which later becomes tunneling insulator 14 was covered with a resist, and the film was subjected to anodization using as electrolyte a mixture of an ammonium tartarate solution (Comparative Example 1) and ethylene glycol to form aluminum oxide on the surface of bottom electrodes 12, thus forming a thick electric field diffuser 13. Anodization was carried out in a constant current mode (current density: 30 μA/cm²) until reaching a voltage of 80 V, and thereafter in a constant voltage mode for one hour.

(3) Then, by using a non-aqueous electrolyte of the present invention shown in Table 1, except for Comparative Example 1, aluminum oxide was deposited on the electron emission region 17 in the surface of bottom electrodes 12 to form a thin tunneling insulator 14. Anodization was conducted in a constant current mode (current density: 10 μA/cm²) until reaching a voltage of 4 V, and thereafter in a constant voltage mode for two hours.

(4) Finally, bus electrodes 15 and top electrodes 16 were formed. Bus electrodes 15 comprised a multi-layer film of aluminum and molybdenum, and top electrodes 16 were formed by sputter-depositing iridium (Ir; 1 nm), platinum (Pt; 2 nm) and gold (Au; 3 nm) successively by shadow mask evaporation without breaking vacuum.

The micro-electron guns of the MIM diode structure fabricated according to the above-described procedure (1)-(4) were placed in a vacuum chamber under a pressure of 1×10⁻⁴ Pa, and bottom electrodes 12 were grounded while applying a voltage of 7.5 V to top electrodes 16, whereat electron emission from top electrodes 16 was confirmed.

Then the initial voltage was set so that diode current density would become 0.4 mA/cm², and the electron guns were operated in this state for one hour, during which period the variation of diode current was recorded.

As a result, it was confirmed that in the case of the micro-electron guns of the MIM diode structure having tunneling insulator 14 formed by anodizing bottom electrodes 12 by using the electrolyte of the present invention, the decrease of current was less than when using a tartaric acid/ethylene glycol mixture of the conventional formulation (Comparative Example 1) as shown in Table 1.

As viewed above, tunneling insulators 14 in the micro-electron guns of the MIM diode structure of Examples 1 to 8 have a low electron trap density and a high electric field and are also minimized in formation of electron traps under the large operating current condition, so that they have excellent life characteristics.

TABLE 1

| | | | | | | Current |
|---|---|---|---|---|---|---|
| | | | | | | rate |
| | | | | | | after |
| | | | | | | one- |
| | | | | | | hour |
| | | | Solute | Water | | oper- |
| | No. | Solute | density | content | Solvent | ation |
| Comp. | 1 | Ammonium | 0.3 wt % | 10 wt % | Ethylene | 60% |
| Ex- | | tartarate | | | glycol | |
| ample | | | | | | |
| Ex- | 1 | Ammonium | 1 wt % | 5 wt % | Ethylene | 95% |
| ample | | salicylate | | | glycol | |
| Ex- | 2 | Ammonium | 1 wt % | 5 wt % | Ethylene | 85% |
| ample | | adipate | | | glycol | |
| Ex- | 3 | Ammonium | ″ | ″ | Ethylene | 88% |
| ample | | maleate | | | glycol | |
| Ex- | 4 | Ammonium | ″ | ″ | Ethylene | 86% |
| ample | | azelate | | | glycol | |
| Ex- | 5 | Ammonium | ″ | ″ | Ethylene | 85% |
| ample | | phthalate | | | glycol | |
| Ex- | 6 | Ammonium | ″ | ″ | Ethylene | 85% |
| ample | | tungstate | | | glycol | |
| Ex- | 7 | Ammonium | 1 wt % | 5 wt % | γ-butyro- | 87% |
| ample | | salicylate | | | lactone | |
| Ex- | 8 | Ammonium | ″ | ″ | Propylene | 90% |
| ample | | salicylate | | | carbonate | |

### EXAMPLE 9

Next, lower substrate 3 having thereon an array (matrix) of micro-electron guns of the MIM diode structure as shown in FIG. 4 was produced according to the above-described procedure. Then this lower substrate 3, upper substrate 5 on which a striped phosphor layer is formed, and glass frame 4 were fused together with a glass paste, with exhaust pipe 6 being also similarly secured in position to constitute a vacuum chamber.

In the above operation, the glass paste was sintered in the atmosphere at 400° C. for 10 minutes. The vacuum chamber was evacuated by an oil diffusion pump, followed by bakeout at 300° C., and at a point when the degree of vacuum reached 7×10⁻⁵ Pa, the exhaust pipe was sealed to complete a display device.

A display test of the device of this Example was conducted in a progressive mode as the operating system of the micro-electron guns of the MIM diode structure. In this progressive mode, a scan pulse of −3.0 V is applied to bottom electrodes 12 of the selected pixels while a data pulse of 4.5 V is applied to top electrodes 16 (via bus electrodes 15), urging the emission of electrons from the electron emission region 17. The emitted electrons are accelerated by the application of acceleration voltage of 3 kV to the inter-substrate gap (2 mm) and reach phosphor stripes 18 to cause luminescence.

On the other hand, in the non-selected pixels, a scan pulse of −3.0 V or a data pulse of 4.5 V is applied to either bottom electrodes 12 or top electrodes 16 (or bus electrodes 15) alone, so that no electrons are emitted from electron emission region 17.

In this display test, the display device of this Example showed outstanding display performance.

While the invention made by the present inventor has been described in detail with respect to certain embodiments thereof, it is obvious that various changes and modifications thereof can be made without departing from the spirit or scope of the invention.

Industrial Applicability

The effects produced by the representative embodiments of the invention disclosed in this application can be epitomized as follows.

The present invention makes it possible to improve the operating life of the displays using the electron guns of the MIM diode structure and has great industrial applicability.

What is claimed is:

1. A process for producing a display having a second substrate with a phosphor layer formed on a surface thereof, and a first substrate disposed opposing to said second substrate and having electron guns formed thereon, said electron guns having a structure of: a first conductive film laminated on the first substrate—an insulating film—a second conductive film, said process comprising: forming the insulating film by anodizing said first conductive film by using a non-aqueous electrolyte containing an organic solvent having an alcoholic hydroxyl group and at least one solute selected from salts of inorganic oxo acids and salts of organic carboxylic acids containing not more than 2 alcoholic hydroxyl groups.

2. A process according to claim 1, wherein the organic solvent having the alcoholic hydroxyl group is ethylene glycol or propylene glycol.

3. A process according to claim 1, wherein said inorganic oxo acid is one or more compounds selected from a group consisting of boric acid, phosphoric acid, sulfuric acid, tungstic acid, molybdic acid, chromic acid and vanadic acid, and said organic carboxylic acid is one or more compounds selected from a group consisting of salicylic acid, adipic acid, azelaic acid, phthalic acid, benzoic acid, γ-resorcylic acid, maleic acid, fumaric acid, itaconic acid, malonic acid, succinic acid, glutaric acid, dimethylmalonic acid and citraconic acid.

4. A process for producing a display having a second substrate with a phosphor layer formed on a surface thereof, and a first substrate disposed opposing to said second substrate and having electron guns formed thereon, said electron guns having a structure of: a first conductive film laminated on the first substrate—an insulating film—a second conductive film, said process comprising: forming the insulating film by anodizing said first conductive film by using a non-aqueous electrolyte containing an aprotic organic solvent and at least one solute selected from salts of inorganic oxo acids and salts of organic carboxylic acids.

5. A process according to claim 4, wherein the aprotic organic solvent is y-butyrolactone or propylene carbonate.

6. A process according to claim 4, wherein said inorganic oxo acid is one or more compounds selected from a group consisting of boric acid, phosphoric acid, sulfuric acid, tungstic acid, molybdic acid, chromic acid and vanadic acid, and said organic carboxylic acid is one or more compounds selected from a group consisting of salicylic acid, adipic acid, azelaic acid, phthalic acid, benzoic acid, γ-resorcylic acid, maleic acid, fumaric acid, itaconic acid, malonic acid, succinic acid, glutaric acid, dimethylmalonic acid and citraconic acid.

7. A process for producing a display having a second substrate with a phosphor layer formed on a surface thereof, and a first substrate disposed opposing to said second substrate and having electron guns formed thereon, said electron guns having a structure of: a first conductive film laminated on the first substrate—an insulating film—a second conductive film, said process comprising: forming the insulating film by anodizing said first conductive film by using a non-aqueous electrolyte containing a mixed solvent comprising an organic solvent having an alcoholic hydroxyl group and an aprotic organic solvent and at least one solute selected from salts of inorganic oxo acids and salts of organic carboxylic acids.

8. A process according to claim 7, wherein the organic solvent having an alcoholic hydroxyl group is ethylene glycol or propylene glycol.

9. A process according to claim 7, wherein said aprotic organic solvent is γ-butyrolactone or propylene carbonate.

10. A process according to claim 7, wherein said inorganic oxo acids is one or more compounds selected from a group consisting of boric acid, phosphoric acid, sulfuric acid, tungstic acid, molybdic acid, chromic acid and vanadic acid, and said organic carboxylic acid is one or more compounds selected from a group consisting of salicylic acid, adipic acid, azelaic acid, phthalic acid, benzoic acid, γ-resorcylic acid, maleic acid, fulmaric acid, itaconic acid, malonic acid, succinic acid, glutaric acid, dimethylmalonic acid and citraconic acid.
